(19) United States
(12) Patent Application Publication
(10) Pub. No.: US 2026/0363036 A1
(43) Pub. Date: Nov. 12, 2026

(54) FORTIFIED DIELECTRIC HARDMASK

(71) Applicant: Applied Materials, Inc., Santa Clara, CA (US)

(72) Inventors: DEVIKA GRANT, Santa Clara, CA (US); RAJESH PRASAD, Gloucester, MA (US); ISHWAR SINGH, Sunnyvale, CA (US); PRASHANT KULSHRESHTHA, Sunnyvale, CA (US); YU YANG, Santa Clara, CA (US); GENE LEE, Santa Clara, CA (US); YEONJU KWAK, Santa Clara, CA (US); SHASHANK SHARMA, Sunnyvale, CA (US); ABHIJIT MALLICK, Fremont, CA (US); SIVANANDHA KANAKASABAPATHY, Pleasanton, CA (US)

(21) Appl. No.: 19/651,446

(22) Filed: Apr. 17, 2026

Related U.S. Application Data
(60) Provisional application No. 63/804,496, filed on May 12, 2025.

(51) Int. Cl. H10P 76/40; C23C 14/48; C23C 16/34; C23C 16/56; H10P 30/40; H10P 95/90

(52) U.S. Cl. CPC H10P 76/4085; C23C 14/48; C23C 16/342; C23C 16/56; H10P 30/40; H10P 76/405; H10P 95/90

(57) ABSTRACT

Embodiments described herein relate to a method that includes forming a dielectric layer over a substrate, where the dielectric layer includes boron. In an embodiment, the method further includes fortifying the dielectric layer with a treatment to form a fortified dielectric layer that has a different composition than the dielectric layer. In an embodiment, the method further includes forming an opening through the dielectric layer.

### CROSS-REFERENCE TO RELATED APPLICATIONS

This application claims the benefit of U.S. Provisional Application No. 63/804,496, filed on May 12, 2025, the entire contents of which are hereby incorporated by reference herein.

### BACKGROUND

### 1. Field

Embodiments relate to the field of semiconductor manufacturing and, in particular, fortified hardmasks and processes for fortifying hardmasks.

### 2. Description of Related Art

In some memory devices, such as DRAM devices, capacitor modules may include dielectric layers as part of the capacitor module. For example, dielectric stacks that include alternating layers of silicon oxide (SiO₂) and silicon carbon nitride (SiCN) may be used as part of the capacitor module for a DRAM device. Etching processes may be used to form contact holes through the dielectric stack in order to form electrical contacts that pass through the dielectric stack. For example, etching processes may include a fluorine based etch (e.g., C₄F₆) with a high bias.

The surface of the dielectric stack (which may also be referred to as a mold in the case of DRAM devices) may be protected by a hardmask during the etching process. The hardmask may have an opening that exposes a portion of the dielectric layer in order to form the contact holes through pattern transfer. Hardmasks are typically designed to have a high etch resistance to the etching chemistry that is used to etch the layers in the dielectric stack. Despite the high etch resistance, the etching processes may result in the rounding of corners of the contact hole formed through the hardmask. When the corner rounding occurs, the quality of the pattern transfer into the underlying dielectric stack is negatively impacted. Corner rounding issues become more problematic as aspect ratios of the contact holes continue to increase.

### SUMMARY

Embodiments described herein relate to a method that includes forming a dielectric layer over a substrate, where the dielectric layer includes boron. In an embodiment, the method further includes fortifying the dielectric layer with a treatment to form a fortified dielectric layer that has a different composition than the dielectric layer. In an embodiment, the method further includes forming an opening through the dielectric layer.

Embodiments described herein relate to a method that includes flowing a first gas including boron into a chamber, and flowing a second gas including one or more of oxygen, sulfur, carbon, or nitrogen into the chamber. In an embodiment, the method further includes depositing a fortified boron-based dielectric layer on a substrate in the chamber using the first gas and the second gas.

Embodiments described herein relate to a material composition that includes boron, hydrogen, and one or more of oxygen, sulfur, carbon, or nitrogen. In an embodiment, the material composition includes at least 70 atomic percent boron, and a remaining total atomic percentage of the material composition includes one or more of oxygen, sulfur, carbon, or nitrogen. In an embodiment, a concentration of bonds between boron and hydrogen is lower than a concentration bonds between boron and the one or more of oxygen, sulfur, carbon, or nitrogen.

### BRIEF DESCRIPTION OF THE DRAWINGS

FIG. 1A is a cross-sectional illustration of a dielectric stack over a substrate and a hardmask over the dielectric stack, in accordance with an embodiment.

FIG. 1B is a cross-sectional illustration of the dielectric stack and hardmask after an opening is formed through the hardmask and the pattern of the opening is transferred into the dielectric stack, in accordance with an embodiment.

FIG. 2A is an FTIR plot of boron-hydrogen bond intensity for an unfortified boron-based dielectric layer and a fortified boron-based dielectric layer, in accordance with an embodiment.

FIG. 2B is an FTIR plot of a boron-oxygen or silicon-oxygen-silicon bond intensity for an unfortified boron-based dielectric layer and a fortified boron-based layer, in accordance with an embodiment.

FIGS. 3A-3C are cross-sectional illustrations that depict a process for fortifying a boron-based dielectric layer through co-flowing a gas with a substitution element that has a higher bond strength with boron than boron-boron bonds, in accordance with an embodiment.

FIG. 4 is a process flow diagram that describes a process for fortifying a boron-based dielectric layer through co-flowing a gas with a substitution element that has a higher bond strength with boron than boron-boron bonds, in accordance with an embodiment.

FIGS. 5A-5C are cross-sectional illustrations that depict a process for fortifying a boron-based dielectric layer through an annealing process, in accordance with an embodiment.

FIGS. 6A-6C are cross-sectional illustrations that depict a process for fortifying a boron-based dielectric layer through an ion implantation process, in accordance with an embodiment.

FIG. 7 is a flow diagram that describes a process for fortifying a boron-based dielectric, in accordance with an embodiment.

FIGS. 8A and 8B are cross-sectional illustrations that depict a process for fortifying a boron-based dielectric layer after a contact hole is opened in the dielectric layer, in accordance with an embodiment.

FIG. 9 is a flow diagram that describes a process for fortifying a boron-based dielectric layer after a contact hole is opened in the dielectric layer, in accordance with an embodiment.

FIG. 10 is a plan view schematic of a cluster tool that may be used to form a fortified boron-based dielectric layer, in accordance with an embodiment.

FIG. 11 illustrates a block diagram of an exemplary computer system that may be used in conjunction with a processing tool, in accordance with an embodiment.

### DETAILED DESCRIPTION

Embodiments described herein include fortified hardmasks and processes for fortifying hardmasks. Numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various ‎embodiments or aspects of the disclosure are described herein. In some ‎implementations, the ‎different embodiments are practiced separately. However, embodiments ‎are not limited to ‎embodiments being practiced in isolation. For example, two or more different ‎embodiments can ‎be combined together in order to be practiced as a single device, process, ‎structure, or the like. ‎The entirety of various embodiments can be combined together in some ‎instances. In other ‎instances, portions of a first embodiment can be combined with portions of ‎one or more ‎different embodiments. For example, a portion of a first embodiment can be ‎combined with a ‎portion of a second embodiment, or a portion of a first embodiment can be ‎combined with a ‎portion of a second embodiment and a portion of a third embodiment.‎

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, dielectric etching often relies on the presence of a hardmask material in order to protect portions of the dielectric layer that are not to be etched. In some instances, such dielectric etching is used in the formation of capacitor modules for memory devices (e.g., DRAM). Though, dielectric etching processes may be used in many different semiconductor technologies. In the particular case of a DRAM device, alternating silicon oxide (SiO₂) and silicon carbon nitride (SiCN) layers may be covered by a boron-based hardmask layer. For example, a boron-silicon hardmask layer may be used as the hardmask.

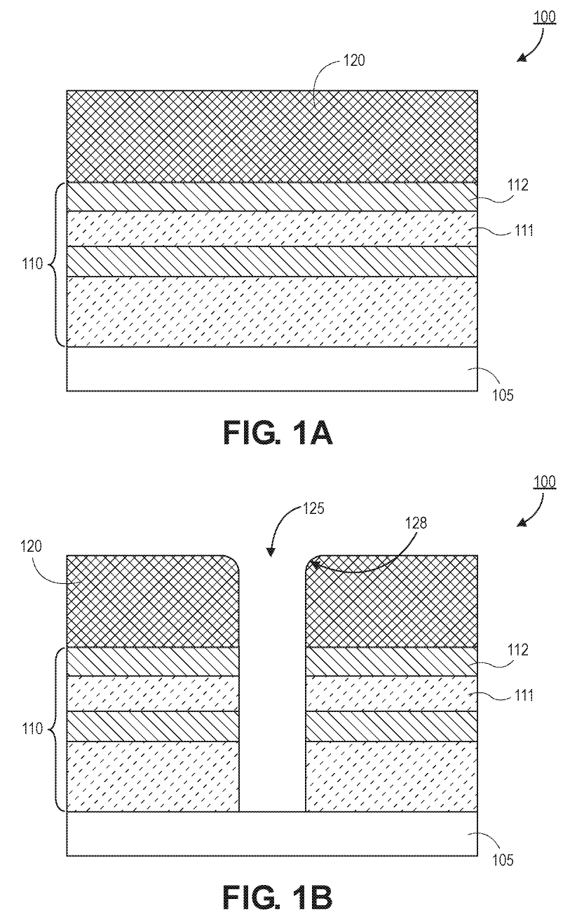

FIGS. 1A and 1B are cross-sectional illustrations that depict a process for forming a pattern in a dielectric stack using a hardmask. In FIG. 1A, a cross-sectional illustration of a device 100 with a dielectric stack 110 that is provided over a substrate 105 is shown. The substrate 105 may comprise a semiconductor substrate, such as a silicon wafer or the like. The dielectric stack 110 in FIG. 1A is shown with alternating first layers 111 and second layers 112. Though, a single dielectric layer may also be used for the dielectric stack 110 in other instances. In the particular case of a DRAM device, the first layers 111 may comprise SiCN and the second layers 112 may comprise SiO₂.

As shown, a hardmask 120 may be provided over the dielectric stack 110. The hardmask 120 may be a material that is etch selective to the underlying dielectric stack 110. For example, in the case of a fluorine base etching chemistry, the hardmask 120 may be more resistant to reaction with the fluorine than the underlying dielectric stack 110. In some dielectric etching processes, the hardmask 120 may comprise a boron-based dielectric material or a boron and silicon-based dielectric material. Embodiments may also include a hardmask 120 that comprises pure boron (or substantially all boron, e.g., greater than 95% boron by weight), or the hardmask 120 may comprise boron and oxygen (e.g., a boron oxide, such as B₂O₃).

Referring now to FIG. 1B, a cross-sectional illustration of the device after a contact hole opening 125 is formed through the hardmask 120 and the dielectric stack 110 is shown. The contact hole opening 125 may first be formed through the hardmask 120 with a contact hole etch that selectively etches the hardmask 120. After the contact hole opening 125 is formed through the hardmask 120, the pattern of the contact hole opening 125 may be transferred into the underlying dielectric stack 110 with an etching process. Typically, the dielectric stack 110 is etched with a fluorine-based etching chemistry. For example, an etching chemistry that comprises C₄F₆ may be used in some instances. The etching process may also be implemented at a high bias to improve the etching performance.

Despite the presence of an etch selectivity between the hardmask 120 and the dielectric stack 110, the hardmask 120 may still partially etch during the pattern transfer into the underlying dielectric stack 110. For example, the corners 128 of the hardmask 120 may be rounded by the etching process. This can result in poor pattern transfer into the underlying dielectric stack 110. The rounding of the corners 128 and/or other damage to the hardmask 120 may be the result of material properties of the hardmask 120 that are not tailored to provide the highest possible etch resistance to the etching chemistry.

For example, existing hardmasks may have a relatively high concentration of hydrogen (e.g., greater than about 1.0 atomic percent). The high concentration of hydrogen provides a sufficient number of hydrogen network terminations within the structure of the hardmask. That is, since hydrogen can only bond to one other element (e.g., boron in the case of the hardmasks described herein), the atomic network is terminated at each hydrogen bond. A higher number of network termination can lead to a weaker hardmask that is more susceptible to etching.

Additionally, the hardmask may preferentially react with fluorine to form volatile byproducts, such as BF. This is due to the enthalpy of BF being higher than other bonds within the hardmask, such as boron-boron bonds, boron-silicon bonds, boron-oxygen bonds, or the like. Accordingly, the hardmasks as they are presently engineered may be thermodynamically more prone to etching than desired.

Accordingly, embodiments disclosed herein may include one or more hardmask deposition and/or fortification options that produce a hardmask material that has a higher etch resistance to fluorine based etching chemistries. This allows for better retention of the pattern in the hardmask and provides better etching results in the underlying dielectric stack. In one embodiment, the hardmask is a boron-based hardmask. As used herein, a boron-based hardmask may refer to a dielectric material that comprises approximately 70 atomic percent boron or higher, approximately 90 atomic percent boron or higher, or approximately 95 atomic percent boron or higher. In some embodiments the boron-based hardmask may also comprise silicon. Other elements (e.g., oxygen, sulfur, carbon, nitrogen, or hydrogen) may also be present within the boron-based hardmask, as will be described in greater detail herein.

In an embodiment, the boron-based hardmask may be formed so that hydrogen concentration is minimized in the hardmask. For example, hydrogen within the boron-based hardmask may be about 1.0 atomic percent or lower, or about 0.5 atomic percent or lower. As noted above, the presence of hydrogen within the boron-based hardmask may result in a large number of network terminations that lead to a weaker material. Accordingly, reducing the hydrogen concentration may provide a more etch resistant hardmask.

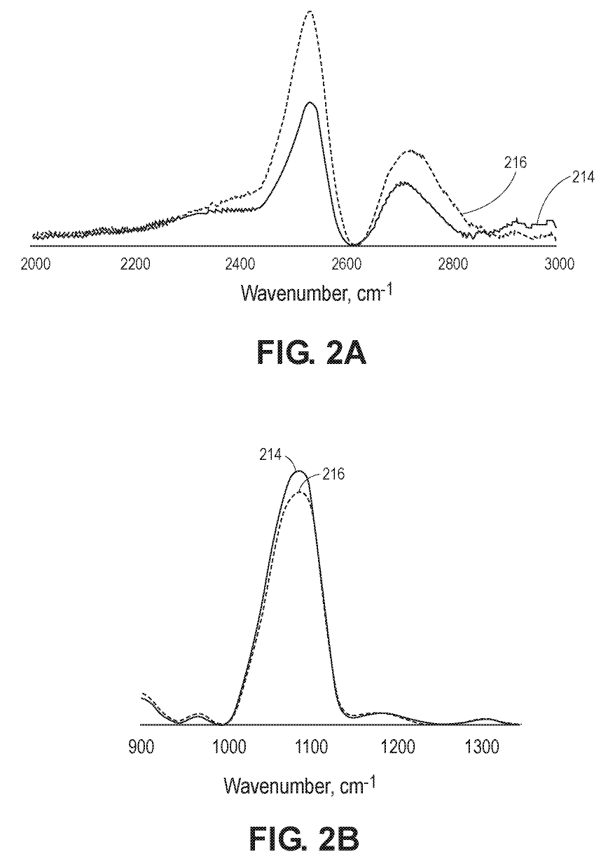

In some instances, the presence of hydrogen may be monitored through an FTIR plot, such as the one shown in FIG. 2A. As shown, the line 216 is a depiction of boron-hydrogen bonds of a typical boron-based hardmask with a hydrogen atomic percentage that is over about 1.0 atomic percent, and the line 214 is a boron-based hardmask with a hydrogen atomic percentage that is about 1.0 atomic percent or less.

In an embodiment, the boron-based hardmask may be deposited with a deposition process that further integrates elements that bond with the boron with higher enthalpy than boron-boron bonds or boron-silicon bonds. Increasing the bond energy makes it harder for high enthalpy boron-fluorine bonds to form. For example, a gas comprising one or more of oxygen, sulfur, carbon, or nitrogen may be flowed into the deposition chamber along with a gas comprising the boron (e.g., in a chemical vapor deposition (CVD) process or a plasma enhanced CVD (PECVD) process).

In the case of oxygen, the boron-oxygen bond has a higher enthalpy than boron-fluorine bonds. Such bonds make the generation of boron-fluorine bonds thermodynamically unfavorable, which improves etch resistance. While sulfur-boron bonds, carbon-boron bonds, and nitrogen-boron bonds are less thermodynamically favorable than boron-fluorine bonds, they have higher enthalpies than boron-boron bonds and boron-silicon bonds. As such, they are at least improved compared to existing boron-based hardmask solutions.

The increased presence of increased boron-oxygen (or boron and other thermodynamically favorable elements) may also be identified through the use of FTIR. For example, FIG. 2B is an illustration of an increase in boron-oxygen bonding between a typical boron-based dielectric (represented by line) 216 and a fortified boron-based dielectric (represented by line 214), such as those that will be described in greater detail herein.

Embodiments disclosed herein may also improve the etch resistance of a boron-based hardmask through the use of densification and/or grain size manipulation. Generally, a denser hardmask material may be more etch resistant. In some embodiments, the density of fortified boron-based hardmask may be approximately 2.0 g/cm³ or higher, or approximately 2.5g/cm³ or higher, whereas existing boron-based hardmask materials are typically around 2.0g/cm³ or lower. Additionally, shrinking the average grain sizes may result in a more etch resistant hardmask material. That is, fortifying the boron-based hardmask by reducing the average grain size of the dielectric material may provide an improvement to etch resistance that is independent of densification. For example, average grain size reduction may reduce the reactive surface area of the boron-based hardmask that is exposed during a fluorine-based etching process.

In the embodiments described herein, the fortification of the boron-based hardmask may be implemented through the combination of one or more processing operations. In one embodiment, the substitution atoms (e.g., oxygen, sulfur, carbon, or nitrogen) may be co-flowed into the chamber during the deposition of the boron-based hardmask. Embodiments may also include infusing the substitution atoms into the hardmask after the hardmask has been deposited. For example, ion implantation may be used to infuse substitution atoms into the hardmask. The ion implantation may occur before hardmask opening processes or after hardmask opening processes. Embodiments may also include implementing an anneal (e.g., a rapid thermal anneal) to modify the structure of the hardmask in order to improve etch resistance. Generally, it has been shown that boron-based hardmasks that have been fortified with one or more operations described herein may exhibit an etch selectivity improvement of at least 10%, at least 20%, or at least 30% relative to an unfortified boron-based hardmask.

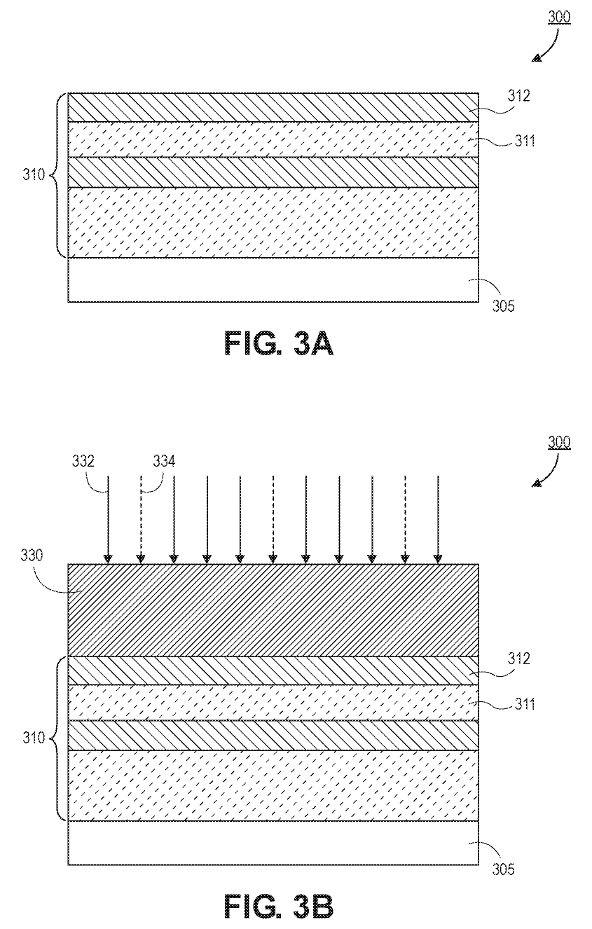

Referring now to FIGS. 3A-3C, a series of cross-sectional illustrations depicting a process for forming a boron-based hardmask with a fortified composition is shown, in accordance with an embodiment. Particularly, the embodiment shown in FIGS. 3A-3C illustrates a process that includes depositing a fortified boron-based hardmask through integration of the substitution atoms (e.g., one or more of oxygen, sulfur, carbon, or nitrogen) during the blanket deposition of the boron-based hardmask.

Referring now to FIG. 3A, a cross-sectional illustration of a device 300 is shown, in accordance with an embodiment. In an embodiment, the device 300 may comprise a dielectric stack 310 that is provided over a substrate 305. The substrate 305 may comprise a semiconductor substrate, such as a silicon wafer or the like. While the dielectric stack 310 is shown as being directly on the substrate 305, it is to be appreciated that intervening layers (not shown) may also be provided between the dielectric stack 310 and the substrate 305.

In the embodiment shown in FIG. 3A, the dielectric stack 310 is depicted with alternating first layers 311 and second layers 312. Though, a single dielectric layer may also be used for the dielectric stack 310 in other instances. Further, any number of different dielectric layers may be stacked in the dielectric stack 310. In the particular case of a DRAM device, the first layers 311 may comprise SiCN and the second layers 312 may comprise SiO₂. Though, any suitable dielectric materials used in semiconductor manufacturing may be included in the dielectric stack 310 in accordance with various embodiments.

Referring now to FIG. 3B, a cross-sectional illustration of the device 300 after a fortified boron-based hardmask 330 is deposited over the dielectric stack 310 is shown, in accordance with an embodiment. In an embodiment, the fortified boron-based hardmask 330 may comprise approximately 75 atomic percent boron or higher, approximately 90 atomic percent boron or higher, or approximately 95 atomic percent boron or higher. In an embodiment, the fortified boron-based hardmask 330 may also comprise silicon (e.g., at least 5.0 atomic percent silicon or at least 10 atomic percent silicon). Additionally, the fortified boron-based hardmask 330 may comprise one or more different types of substitution atoms that minimize the formation of network terminations (formed by hydrogen bonds). For example, the substitution atoms may comprise one or more of oxygen, sulfur, carbon, or nitrogen. In an embodiment, a concentration of the one or more substitution atoms may be up to approximately 10 atomic percent.

In an embodiment, the fortified hardmask 330 may be formed with a vapor deposition process, such as a CVD process, a PECVD process, or the like. In an embodiment, the deposition process may include the flow of a first gas 332 that comprises boron and a second gas 334 that comprises the one or more substitution atoms. In an embodiment, the reaction of the gasses at a surface of the device 300 may result in the formation of the fortified hardmask 330.

In an embodiment, the deposition process may be implemented at an elevated temperature. For example, a deposition temperature may be implemented at approximately 400° C or higher. Depositing the fortified hardmask 330 at an elevated temperature may reduce the concentration of hydrogen in the fortified hardmask 330. For example, the fortified hardmask 330 may have a concentration of hydrogen that is approximately 1.0 atomic percent or less.

In some embodiments, an additional treatment after deposition may be used to improve etch resistance of the fortified hardmask 330. For example, an ion implantation of noble elements (e.g., helium, neon, argon, krypton, xenon, etc.) may be implemented into the surface of the fortified hardmask 330 in order to break up boron-hydrogen bonds. For example the ions may be implanted with a dose between approximately 1E14 ions/cm² to approximately 1E17 ions/cm², and with an implant energy between approximately 1keV to approximately 1MeV. The implantation temperature may be below 0°C (e.g., to about -100° C), about room temperature, or at an elevated temperature between about 150° C and about 700° C. The implant angle may be any angle between about 0° and about 90°.

In some embodiments, the fortified hardmask 330 may then be annealed (e.g., with a rapid thermal anneal). The anneal may be implemented at a temperature between about 400° C and about 1,100° C, and for a duration up to about 10 seconds or up to about 5 seconds. The use of such an annealing process may allow for the preferential reformation of bonds between boron and the one or more substitution atoms (e.g., oxygen, sulfur, carbon, or nitrogen). Though, it is to be appreciated that an anneal may be omitted in some embodiments. In some embodiments, the implantation and/or annealing process may also be used to modify grain size and/or density of the fortified hardmask 330. Increasing density and/or reducing grain size may further improve etch resistance.

Referring now to FIG. 3C, a cross-sectional illustration of the device 300 after an opening 325 is formed into the fortified hardmask 330 and into the dielectric stack 310 is shown, in accordance with an embodiment. In an embodiment, the opening 325 may be formed through the fortified hardmask 330 with a first etching process. Thereafter, the pattern of the opening 325 may be transferred into the underlying dielectric stack 310. For example, a fluorine-based etching chemistry (e.g., C₄F₆) may be used to etch the underlying dielectric stack 310. In an embodiment, the fortified hardmask 330 may be more resistant to the fluorine etching chemistry. As such, the corners 328 of the opening 325 retain their profile better and produce a better pattern transfer into the underlying dielectric stack 310.

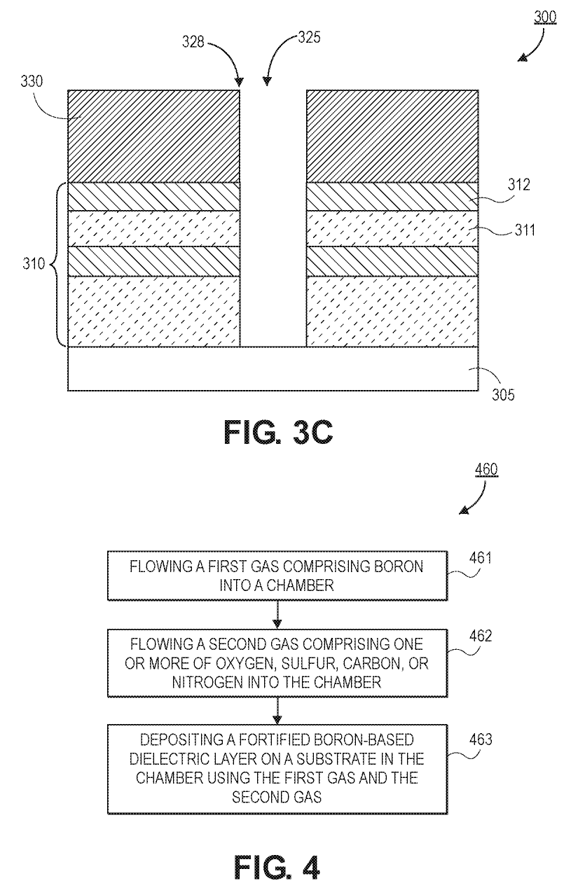

Referring now to FIG. 4, a flow diagram that depicts a process 460 for forming a fortified boron-based hardmask is shown, in accordance with an embodiment. In an embodiment, the boron-based hardmask may be similar to any of the boron-based hardmasks described herein. Further, the process 460 may be similar to one or more portions of the processing operations described with respect to FIGS. 3A-3C.

In an embodiment, the process 460 may begin with operation 461, which comprises flowing a first gas comprising boron into a chamber, and operation 462 which comprises flowing a second gas comprising one or more of oxygen, sulfur, carbon, or nitrogen into the chamber. The first gas and the second gas may be flowed into the chamber at the same time, or the first gas and the second gas may be flowed into the chamber in an alternating sequence. The chamber may be a CVD chamber, a PECVD chamber or the like.

In an embodiment, the process 460 may continue with operation 463, which comprises depositing a fortified boron-based dielectric layer on a substrate in the chamber using the first gas and the second gas. In an embodiment, a temperature during deposition may be about 400° C or higher. The fortified boron-based dielectric layer may then be subjected to an inert ion implantation process and/or a rapid thermal annealing process.

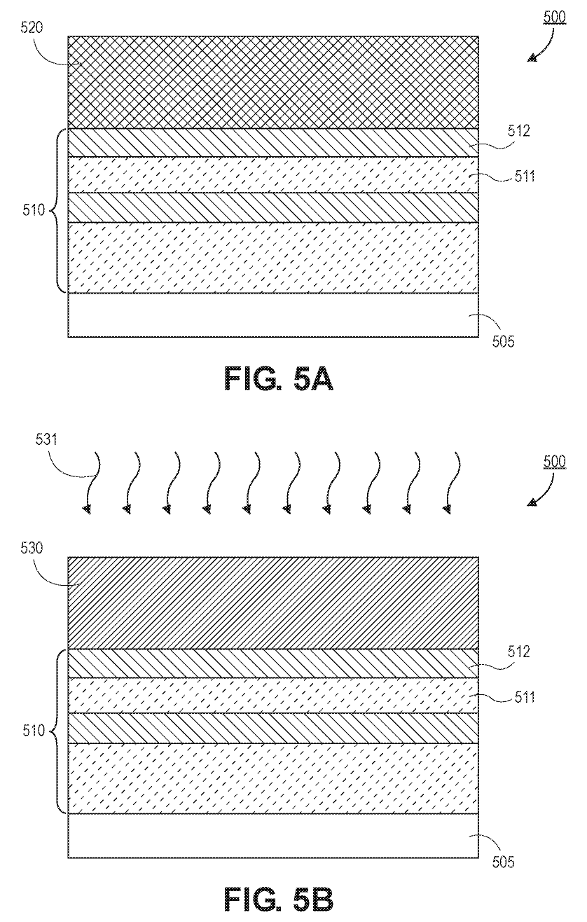

Referring now to FIGS. 5A-5C, a series of cross-sectional illustrations depicting a process for forming a boron-based hardmask with a fortified composition is shown, in accordance with an embodiment. Particularly, the embodiment shown in FIGS. 5A-5C illustrates a process that includes depositing a boron-based hardmask followed by an annealing process in order to fortify the boron-based hardmask. For example, the annealing process may densify the film and/or remove small molecular fragments (e.g., hydrogen terminations) in order to improve etch resistance of the fortified boron-based hardmask.

Referring now to FIG. 5A, a cross-sectional illustration of a device 500 is shown, in accordance with an embodiment. In an embodiment, the device 500 may comprise a dielectric stack 510 that is provided over a substrate 505. The substrate 505 may comprise a semiconductor substrate, such as a silicon wafer or the like. While the dielectric stack 510 is shown as being directly on the substrate 505, it is to be appreciated that intervening layers (not shown) may also be provided between the dielectric stack 510 and the substrate 505.

In the embodiment shown in FIG. 5A, the dielectric stack 510 is depicted with alternating first layers 511 and second layers 512. Though, a single dielectric layer may also be used for the dielectric stack 510 in other instances. Further, any number of different dielectric layers may be stacked in the dielectric stack 510. In the particular case of a DRAM device, the first layers 511 may comprise SiCN and the second layers 512 may comprise SiO₂. Though, any suitable dielectric materials used in semiconductor manufacturing may be included in the dielectric stack 510 in accordance with various embodiments.

In an embodiment, a boron-based hardmask 520 may be deposited over the dielectric stack 510. The boron-based hardmask 520 may comprise silicon in some embodiments. The boron-based hardmask 520 may be deposited with any suitable process, such as a CVD process, a PECVD process, or the like. In some embodiments, a deposition temperature of the boron-based hardmask 520 may be approximately 400° C or higher.

Referring now to FIG. 5B, a cross-sectional illustration of the device 500 after an annealing process (represented by lines 531) is implemented on the hardmask 520 in order to form a fortified boron-based hardmask 530 is shown, in accordance with an embodiment. In an embodiment, the annealing process may result in the removal of hydrogen and/or increase a density of the fortified hardmask 530. In some embodiments, the fortified hardmask 530 may be annealed with a rapid thermal anneal. The anneal may be implemented at a temperature between about 400° C and about 1,100° C, and for a duration up to about 10 seconds or up to about 5 seconds.

Referring now to FIG. 5C, a cross-sectional illustration of the device 500 after an opening 525 is formed into the fortified hardmask 530 and into the dielectric stack 510 is shown, in accordance with an embodiment. In an embodiment, the opening 525 may be formed through the fortified hardmask 530 with a first etching process. Thereafter, the pattern of the opening 525 may be transferred into the underlying dielectric stack 510. For example, a fluorine-based etching chemistry (e.g., C₄F₆) may be used to etch the underlying dielectric stack 510. In an embodiment, the fortified hardmask 530 may be more resistant to the fluorine etching chemistry. As such, the corners 528 of the opening 525 retain their profile better and produce a better pattern transfer into the underlying dielectric stack 510.

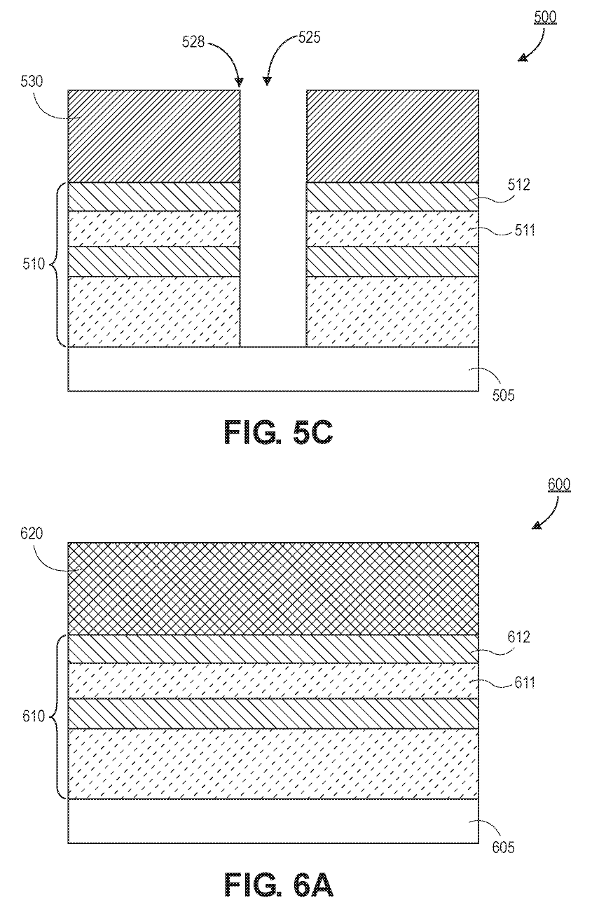

Referring now to FIGS. 6A-6C, a series of cross-sectional illustrations depicting a process for forming a boron-based hardmask with a fortified composition is shown, in accordance with an embodiment. Particularly, the embodiment shown in FIGS. 6A-6C illustrates a process that includes depositing a boron-based hardmask followed by an infusion process in order to fortify the boron-based hardmask. For example, the infusion process may incorporate substitution atoms (e.g., oxygen, sulfur, carbon, or nitrogen) that bond with the boron (or silicon) to form boron-X-boron bonds, where X comprises one or more of oxygen, sulfur, carbon, or nitrogen. In an embodiment, the boron-X-boron bonds have a higher enthalpy than boron-boron or boron-silicon bonds. As such, the etch resistance is improved.

Referring now to FIG. 6A, a cross-sectional illustration of a device 600 is shown, in accordance with an embodiment. In an embodiment, the device 600 may comprise a dielectric stack 610 that is provided over a substrate 605. The substrate 605 and the dielectric stack 610 may be similar to any of those described in greater detail herein. For example, the dielectric stack 610 may have alternating first layers 611 and second layers 612. In an embodiment, the first layers 611 may comprise SiCN and the second layers 612 may comprise SiO₂. Though, any suitable dielectric materials used in semiconductor manufacturing may be included in the dielectric stack 610 in accordance with various embodiments.

In an embodiment, a boron-based hardmask 620 may be deposited over the dielectric stack 610. The boron-based hardmask 620 may comprise silicon in some embodiments. The boron-based hardmask 620 may be deposited with any suitable process, such as a CVD process, a PECVD process, or the like. In some embodiments, a deposition temperature of the boron-based hardmask 620 may be approximately 400° C or higher.

Referring now to FIG. 6B, a cross-sectional illustration of the device 600 after an infusion process (represented by lines 637) is implemented on the hardmask 620 in order to form a fortified boron-based hardmask 630 is shown, in accordance with an embodiment. In an embodiment, the infusion process may include an ion implantation process. For example, one or more of the substitution atoms (e.g., oxygen, sulfur, carbon, or nitrogen) may be implanted into the hardmask 620. For example the ions may be implanted with a dose between approximately 1E14 ions/cm² to approximately 1E17 ions/cm², and with an implant energy between approximately 0.1keV to approximately 300keV. The implantation temperature may be below 0° C (e.g., to about -100° C), about room temperature, or at an elevated temperature between about 150° C and about 700° C. The implant angle may be any angle between about 0° and about 90°.

In some embodiments, the ion implantation process may further comprise an initial inert ion implantation process in order to break existing boron-boron and/or boron-silicon bonds before the substitution ions are implanted. This may make it easier to form the thermodynamically favorable bonds between the boron (and/or silicon) and the substitution ions. For example an inert ion implantation may include inert ions (e.g., helium, neon, argon, krypton, xenon, etc.) that are implanted with a dose between approximately 1E14 ions/cm² to approximately 1E17 ions/cm², and with an implant energy between approximately 1keV to approximately 1MeV. The implantation temperature may be below 0° C (e.g., to about -100° C), about room temperature, or at an elevated temperature between about 150° C and about 700° C. The implant angle may be any angle between about 0° and about 90°.

In some embodiments, the fortified hardmask 630 may be annealed with a rapid thermal anneal in order to drive the formation of the desired bonds between the boron (and/or silicon) and the one or more substitution ions. The anneal may be implemented at a temperature between about 700° C and about 1,100° C, and for a duration up to about 10 seconds or up to about 5 seconds.

Referring now to FIG. 6C, a cross-sectional illustration of the device 600 after an opening 625 is formed into the fortified hardmask 630 and into the dielectric stack 610 is shown, in accordance with an embodiment. In an embodiment, the opening 625 may be formed through the fortified hardmask 630 with a first etching process. Thereafter, the pattern of the opening 625 may be transferred into the underlying dielectric stack 610. For example, a fluorine-based etching chemistry (e.g., C₄F₆) may be used to etch the underlying dielectric stack 610. In an embodiment, the fortified hardmask 630 may be more resistant to the fluorine etching chemistry. As such, the corners 628 of the opening 625 retain their profile better and produce a better pattern transfer into the underlying dielectric stack 610.

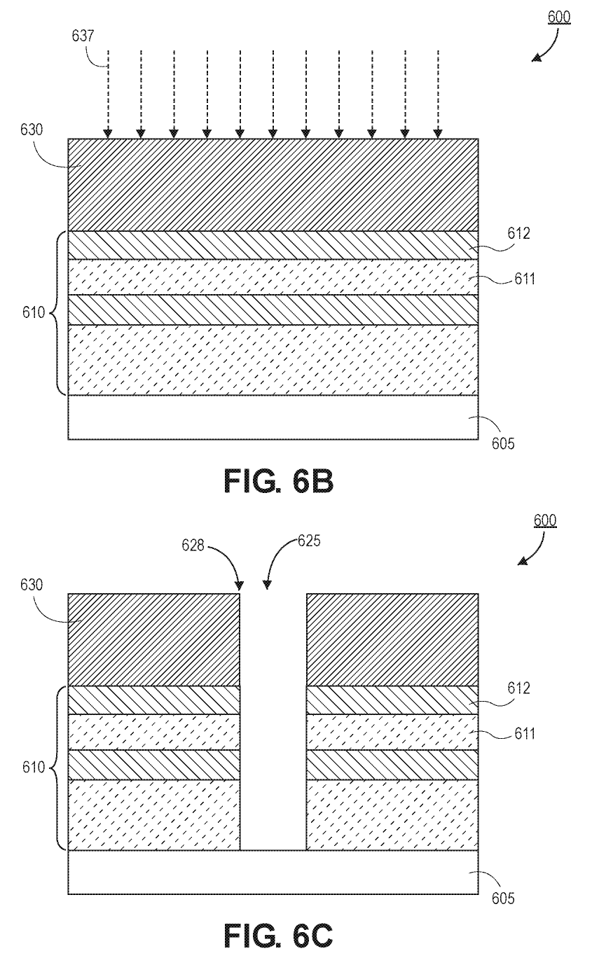

Referring now to FIG. 7, a flow diagram that depicts a process 770 for forming a fortified boron-based hardmask is shown, in accordance with an embodiment. In an embodiment, the boron-based hardmask may be similar to any of the boron-based hardmasks described herein. Further, the process 770 may be similar to one or more portions of the processing operations described with respect to FIGS. 5A-5C and/or 6A-6C.

In an embodiment, the process 770 may begin with operation 771, which comprises forming a dielectric layer over a substrate. In an embodiment, the dielectric layer may be a boron-based hardmask material. The boron-based hardmask material may also comprise silicon in some embodiments. The dielectric layer may be deposited over a dielectric stack similar to any of the dielectric stacks described in greater detail herein. The dielectric layer may be formed with a deposition temperature of 400° C or higher.

In an embodiment, the process 770 may continue with operation 772, which comprises fortifying the dielectric layer with a treatment to form a fortified dielectric layer that has a different composition than the dielectric layer. In an embodiment, the treatment may comprise one or more of an anneal, an ion implantation with inert ions, and/or an ion implantation with substitute ions (e.g., oxygen, sulfur, carbon, nitrogen, or the like). In an embodiment, the treatments may be similar to any of the annealing and/or ion implantation treatments described in greater detail herein. For example, an annealing treatment may include a rapid thermal anneal or the like. The treatments may be applied in any suitable order in order to provide a desired result.

In an embodiment, the fortified dielectric layer may comprise at least 90 atomic percent boron. In some embodiments, the fortified dielectric layer may also comprise at least 10 atomic percent silicon. In an embodiment, a total atomic percentage of the one or more of oxygen, sulfur, carbon, or nitrogen is up to 10 atomic percent of the material composition. Further, a concentration of bonds between boron and hydrogen may be lower than a concentration bonds between boron and the one or more of oxygen, sulfur, carbon, or nitrogen. In an embodiment, the fortified dielectric layer may have a concentration of hydrogen that is up to approximately 1.0 atomic percent.

In an embodiment, the process 770 may continue with operation 773, which comprises forming an opening through the dielectric layer. In an embodiment, the opening may be formed through the fortified dielectric layer with a first etching process. Thereafter, the pattern of the opening may be transferred into an underlying layer (e.g., an underlying dielectric stack). For example, a fluorine-based etching chemistry (e.g., C₄F₆) may be used to etch the underlying layer. In an embodiment, the fortified hardmask may be more resistant to the fluorine etching chemistry. As such, the corners of the opening retain their profile better and produce a better pattern transfer into the underlying layer.

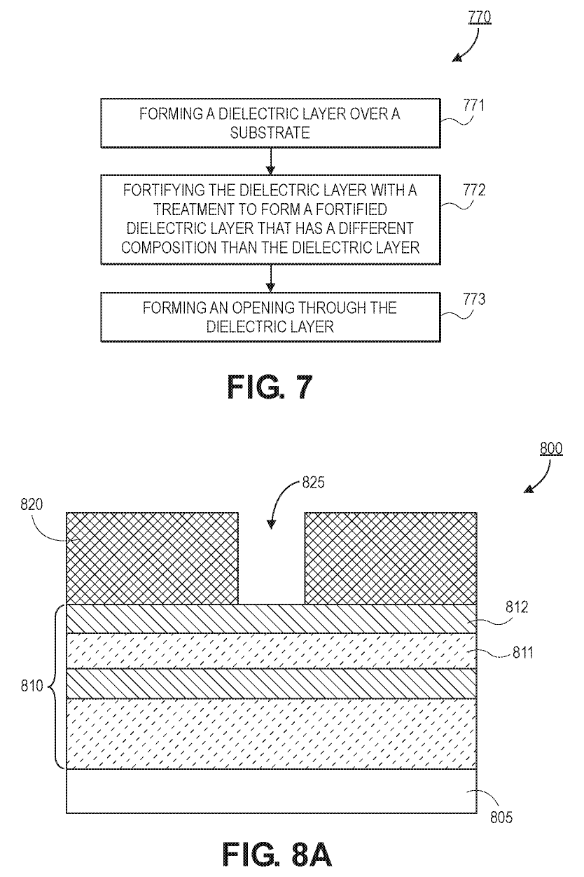

Referring now to FIGS. 8A and 8B, a series of cross-sectional illustrations depicting a process for forming a boron-based hardmask with a fortified composition is shown, in accordance with an embodiment. Particularly, the embodiment shown in FIGS. 8A and 8B illustrates a process that includes depositing a boron-based hardmask followed by a hardmask opening process before an infusion process is used to fortify the boron-based hardmask. For example, the infusion process may incorporate substitution atoms (e.g., oxygen, sulfur, carbon, or nitrogen) that bond with the boron (or silicon) with a higher enthalpy than boron-boron or boron-silicon bonds. As such, the etch resistance is improved.

Referring now to FIG. 8A, a cross-sectional illustration of a device 800 is shown, in accordance with an embodiment. In an embodiment, the device 800 may comprise a dielectric stack 810 that is provided over a substrate 805. The substrate 805 and the dielectric stack 810 may be similar to any of those described in greater detail herein. For example, the dielectric stack 810 may have alternating first layers 811 and second layers 812. In an embodiment, the first layers 811 may comprise SiCN and the second layers 812 may comprise SiO₂. Though, any suitable dielectric materials used in semiconductor manufacturing may be included in the dielectric stack 810 in accordance with various embodiments.

In an embodiment, a boron-based hardmask 820 may be deposited over the dielectric stack 810. The boron-based hardmask 820 may comprise silicon in some embodiments. The boron-based hardmask 820 may be deposited with any suitable process, such as a CVD process, a PECVD process, or the like. In some embodiments, a deposition temperature of the boron-based hardmask 820 may be approximately 400° C or higher.

In an embodiment, a hardmask opening 825 is formed through the hardmask 820. The hardmask opening 825 may be formed with any suitable etching process and/or chemistry. That is, the hardmask opening 825 may be formed before the hardmask 820 is fortified. This order of operations may allow for a simpler (e.g., faster) hardmask opening process since the etch resistance of the hardmask 820 is lower than after the hardmask 820 is fortified.

Referring now to FIG. 8B, a cross-sectional illustration of the device 800 after an infusion process is implemented on the hardmask 820 in order to form a fortified boron-based hardmask 830 is shown, in accordance with an embodiment. In an embodiment, the infusion process 837 may include an ion implantation process and/or an annealing process. For example, the annealing process described with respect to FIG. 5B and/or the ion implantation process described with respect to FIG. 6B may be used to fortify the patterned hardmask 820 to form the fortified hardmask 830. An ion implantation process (which may also comprise a subsequent anneal) may drive the replacement of boron-boron bonds and/or boron-silicon bonds with boron-X-boron bonds, where X comprises one or more of oxygen, sulfur, carbon, or nitrogen.

In the case of an ion implantation process, one or more of the substitution atoms (e.g., oxygen, sulfur, carbon, or nitrogen) may be implanted into the hardmask 820. For example the ions may be implanted with a dose between approximately 1E14 ions/cm² to approximately 1E17 ions/cm², and with an implant energy between approximately 0.1keV to approximately 120keV. The implantation temperature may be below 0°C (e.g., to about -100° C), about room temperature, or at an elevated temperature between about 150° C and about 700° C. The implant angle may be any angle between about 0° and about 20°.

In some embodiments, the ion implantation process may further comprise an initial inert ion implantation process in order to break existing boron-boron and/or boron-silicon bonds before the substitution ions are implanted. This may make it easier to form the thermodynamically favorable bonds between the boron (and/or silicon) and the substitution ions. For example an inert ion implantation may include inert ions (e.g., helium, neon, argon, krypton, xenon, etc.) that are implanted with a dose between approximately 1E14 ions/cm² to approximately 1E17 ions/cm², and with an implant energy between approximately 0.5keV to approximately 120keV. The implantation temperature may be below 0° C (e.g., to about -100° C), about room temperature, or at an elevated temperature between about 150° C and about 700° C. The implant angle may be any angle between about 0° and about 20°.

In some embodiments, the fortified hardmask 830 may be annealed with a rapid thermal anneal in order to drive the formation of the desired bonds between the boron (and/or silicon) and the one or more substitution ions. The anneal may be implemented at a temperature between about 400° C and about 1,100° C, and for a duration up to about 10 seconds or up to about 5 seconds.

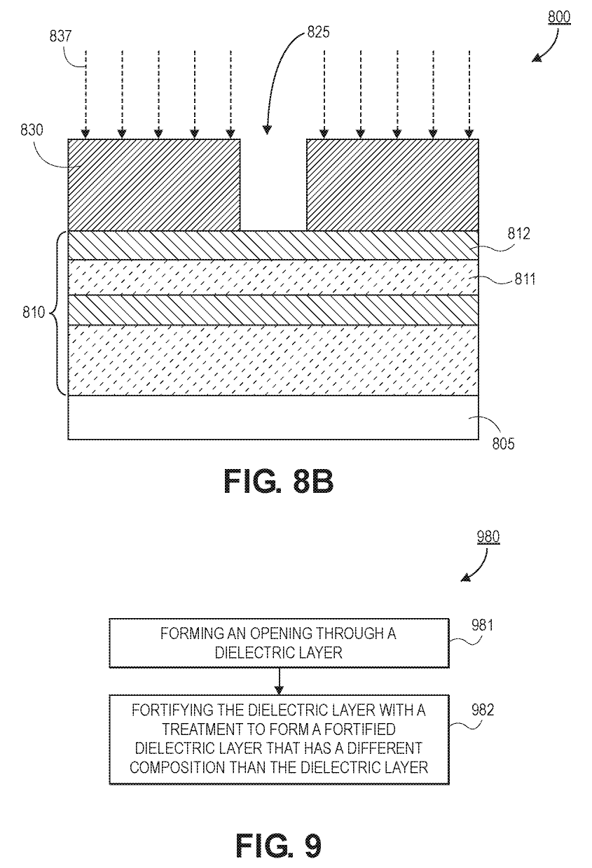

Referring now to FIG. 9, a flow diagram that depicts a process 980 for forming a fortified boron-based hardmask is shown, in accordance with an embodiment. In an embodiment, the boron-based hardmask may be similar to any of the boron-based hardmasks described herein. Further, the process 980 may be similar to one or more portions of the processing operations described with respect to FIGS. 8A and 8B.

In an embodiment, the process 980 may begin with operation 981, which comprises forming an opening through a dielectric layer that is formed over a substrate. In an embodiment, the dielectric layer may be a boron-based hardmask material. The boron-based hardmask material may also comprise silicon in some embodiments. The dielectric layer may be deposited over a dielectric stack similar to any of the dielectric stacks described in greater detail herein. The dielectric layer may be formed with a deposition temperature of 400° C or higher. In an embodiment, the opening may be formed through the dielectric layer with an etching process.

In an embodiment, the process 980 may continue with operation 982, which comprises fortifying the dielectric layer with a treatment to form a fortified dielectric layer that has a different composition than the dielectric layer. In an embodiment, the treatment may comprise one or more of an anneal, an ion implantation with inert ions, and/or an ion implantation with substitute ions (e.g., oxygen, sulfur, carbon, nitrogen, or the like). In an embodiment, the treatments may be similar to any of the annealing and/or ion implantation treatments described in greater detail herein. For example, an annealing treatment may include a rapid thermal anneal or the like. The treatments may be applied in any suitable order in order to provide a desired result.

In an embodiment, the fortified dielectric layer may comprise at least 90 atomic percent boron. In some embodiments, the fortified dielectric layer may also comprise at least 10 atomic percent silicon. In an embodiment, a total atomic percentage of the one or more of oxygen, sulfur, carbon, or nitrogen is up to 10 atomic percent of the material composition. Further, a concentration of bonds between boron and hydrogen may be lower than a concentration bonds between boron and the one or more of oxygen, sulfur, carbon, or nitrogen. In an embodiment, the fortified dielectric layer may have a concentration of hydrogen that is up to approximately 1.0 atomic percent.

In an embodiment, the process 980 may continue with transferring the pattern of the opening into an underlying layer (e.g., an underlying dielectric stack). For example, a fluorine-based etching chemistry (e.g., C₄F₆) may be used to etch the underlying layer. In an embodiment, the fortified hardmask may be more resistant to the fluorine etching chemistry. As such, the corners of the opening retain their profile better and produce a better pattern transfer into the underlying layer.

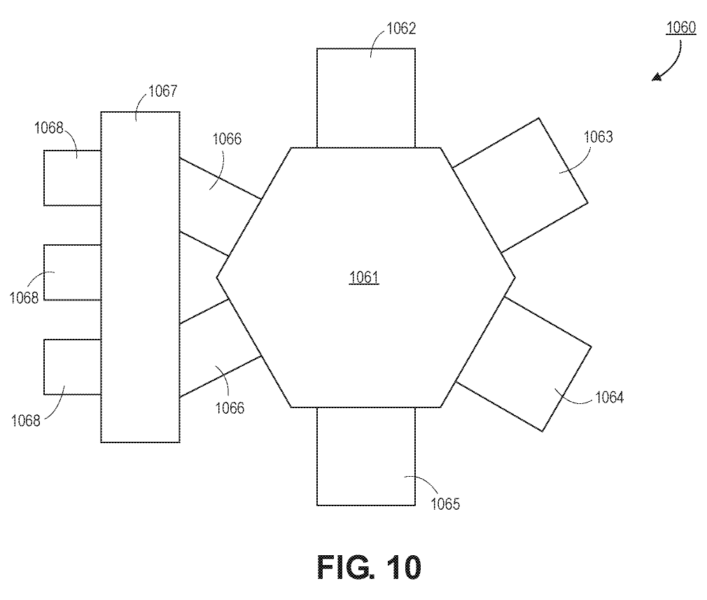

Referring now to FIG. 10, a plan view illustration of a processing tool 1060 that is used to process substrates that include a fortified boron-based hardmask layer is shown, in accordance with an embodiment. In an embodiment, the processing tool 1060 may comprise a transfer chamber 1061 that is coupled to a plurality of processing chambers and/or stations 1062 – 1065. One or more of the processing chambers and/or stations 1062 – 1065 may be suitable for depositing the boron-based hardmask on substrates, and one or more of the processing chambers and/or stations 1062 – 1065 may be suitable for fortifying the boron-based hardmask. In some embodiments, the boron-based hardmask may be deposited and fortified within the same processing chamber and/or station 1062 – 1065. For example, the one or more processing chambers and/or stations 1062 – 1065 may comprise one or more of a CVD chamber, a PECVD chamber, an ion implantation tool, a rapid thermal annealing tool, and/or the like.

In an embodiment, the processing tool 1060 may further comprise one or more load locks 1066 to couple the vacuum environment of the transfer chamber 1061 to a factory interface (FI) 1067. The FI 1067 may receive one or more substrate carriers 1068, such as front opening unified pods (FOUPS) or the like.

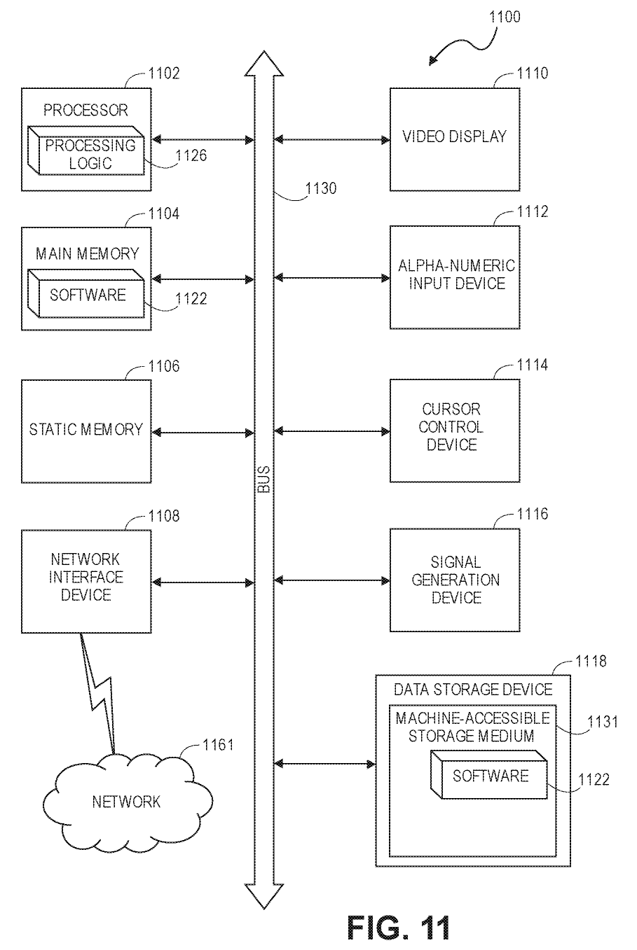

Referring now to FIG. 11, a block diagram of an exemplary computer system 1100 of a processing tool is illustrated in accordance with an embodiment. In an embodiment, computer system 1100 is coupled to and controls processing in the processing tool. Computer system 1100 may be connected (e.g., networked) to other machines in a Local Area Network (LAN), an intranet, an extranet, or the Internet. Computer system 1100 may operate in the capacity of a server or a client machine in a client-server network environment, or as a peer machine in a peer-to-peer (or distributed) network environment. Computer system 1100 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1100, the term “machine” shall also be taken to include any collection of machines (e.g., computers) that individually or jointly execute a set (or multiple sets) of instructions to perform any one or more of the methodologies described herein.

Computer system 1100 may include a computer program product, or software 1122, having a non-transitory machine-readable medium having stored thereon instructions, which may be used to program computer system 1100 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1100 includes a system processor 1102, a main memory 1104 (e.g., read-only memory (ROM), flash memory, dynamic random access memory (DRAM) such as synchronous DRAM (SDRAM) or Rambus DRAM (RDRAM), etc.), a static memory 1106 (e.g., flash memory, static random access memory (SRAM), etc.), and a secondary memory 1118 (e.g., a data storage device), which communicate with each other via a bus 1130.

System processor 1102 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1102 may also be one or more special-purpose processing devices such as an application specific integrated circuit (ASIC), a field programmable gate array (FPGA), a digital signal system processor (DSP), network system processor, or the like. System processor 1102 is configured to execute the processing logic 1126 for performing the operations described herein.

The computer system 1100 may further include a system network interface device 1108 for communicating with other devices or machines. The computer system 1100 may also include a video display unit 1110 (e.g., a liquid crystal display (LCD), a light emitting diode display (LED), or a cathode ray tube (CRT)), an alphanumeric input device 1112 (e.g., a keyboard), a cursor control device 1114 (e.g., a mouse), and a signal generation device 1116 (e.g., a speaker).

The secondary memory 1118 may include a machine-accessible storage medium 1131 (or more specifically a computer-readable storage medium) on which is stored one or more sets of instructions (e.g., software 1122) embodying any one or more of the methodologies or functions described herein. The software 1122 may also reside, completely or at least partially, within the main memory 1104 and/or within the system processor 1102 during execution thereof by the computer system 1100, the main memory 1104 and the system processor 1102 also constituting machine-readable storage media. The software 1122 may further be transmitted or received over a network 1161 via the system network interface device 1108. In an embodiment, the network interface device 1108 may operate using RF coupling, optical coupling, acoustic coupling, or inductive coupling.

While the machine-accessible storage medium 1131 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
forming a dielectric layer over a substrate, wherein the dielectric layer comprises boron;
fortifying the dielectric layer with a treatment to form a fortified dielectric layer that has a different composition than the dielectric layer; and
forming an opening through the dielectric layer.

2. The method of claim 1, wherein fortifying the dielectric layer comprises implanting one or more of oxygen, sulfur, carbon, or nitrogen into the dielectric layer with an ion implantation process.

3. The method of claim 2, wherein the dielectric layer is fortified before forming the opening through the dielectric layer.

4. The method of claim 2, wherein the dielectric layer is fortified after forming the opening through the dielectric layer.

5. The method of claim 1, wherein fortifying the dielectric layer comprises:
annealing the dielectric layer.

6. The method of claim 5, wherein annealing the dielectric layer comprises a rapid thermal anneal at a temperature between 400° C and 1,100° C.

7. The method of claim 6, wherein the rapid thermal anneal has a duration of 10 seconds or less.

8. The method of claim 5, further comprising:
implanting a noble element into the dielectric layer prior to fortifying the dielectric layer.

9. The method of claim 1, wherein the dielectric layer is deposited at a temperature of 400°C or higher.

10. The method of claim 9, wherein the dielectric layer comprises an atomic percentage of hydrogen that is 1.0 atomic percent or less.

11. The method of claim 1, wherein the dielectric layer comprises substantially all boron, wherein the dielectric layer comprises boron and silicon, or wherein the dielectric layer comprises boron and oxygen.

12. A method, comprising:
flowing a first gas comprising boron into a chamber;
flowing a second gas comprising one or more of oxygen, sulfur, carbon, or nitrogen into the chamber; and
depositing a fortified boron-based dielectric layer on a substrate in the chamber using the first gas and the second gas.

13. The method of claim 12, wherein an atomic percentage of oxygen, sulfur, carbon, and/or nitrogen comprises up to 10 atomic percent of a composition of the fortified boron-based dielectric layer.

14. The method of claim 12, wherein depositing the fortified boron-based dielectric layer is done with a chemical vapor deposition process or a plasma enhanced chemical vapor deposition process.

15. The method of claim 12, wherein a temperature of the substrate is at least 400°C during while depositing the fortified boron-based dielectric layer.

16. The method of claim 12, further comprising:
implanting a noble element into the fortified boron-based dielectric layer.

17. The method of claim 16, further comprising:
annealing the fortified boron-based dielectric layer with a rapid thermal anneal with a duration of up to 10 seconds and a temperature between 400°C and 1,100°C after the noble element is implanted into the fortified boron-based dielectric layer.

18. A material composition, comprising boron, hydrogen, and one or more of oxygen, sulfur, carbon, or nitrogen, wherein the material composition comprises at least 70 atomic percent boron, where a remaining total atomic percentage of the material composition comprises one or more of oxygen, sulfur, carbon, or nitrogen, and wherein a concentration of bonds between boron and hydrogen is lower than a concentration bonds between boron and oxygen, boron and sulfur, boron and carbon, and/or boron and nitrogen.

19. The material composition of claim 18, wherein a concentration of hydrogen is 1.0 atomic percent or lower.

20. The material composition of claim 18, further comprising silicon.
